(19) United States
(12) Patent Application Publication
(10) Pub. No.: US 2023/0197610 A1
(43) Pub. Date: Jun. 22, 2023

(54) CONDUCTIVE LINE STRUCTURE HAVING CORRUGATED SURFACE

(71) Applicant: GlobalFoundries Singapore Pte. Ltd., Singapore (SG)

(72) Inventors: KAI KANG, Singapore (SG); WANBING YI, Singapore (SG); RAN XING ONG, Singapore (SG); CURTIS CHUN-I HSIEH, Singapore (SG); JUAN BOON TAN, Singapore (SG)

(21) Appl. No.: 17/645,306

(22) Filed: Dec. 20, 2021

(51) Int. Cl. H01L 23/528; H01L 21/768

(52) U.S. Cl. CPC H01L 23/5283; H01L 21/76877

(57) ABSTRACT

The disclosed subject matter relates generally to structures in semiconductor devices and integrated circuit (IC) chips. More particularly, the present disclosure relates to a structure for use in a conductive line. The present disclosure also relates to a method of forming the structures. The present disclosure provides a structure in a semiconductor device, the structure having a corrugated surface on at least one of its sides. The disclosed structures may have smaller or no micro-trenches and may therefore increase the breakdown voltage of the structures.

### FIELD OF THE INVENTION

The present disclosure relates generally to structures in semiconductor devices and integrated circuit (IC) chips. More particularly, the present disclosure relates to a structure for use in a conductive line. The present disclosure also relates to a method of forming the structures.

### BACKGROUND

Interconnect features, such as conductive lines or interconnect vias, are used extensively in semiconductor devices and are typically used to connect metallization levels. Formation of these interconnect features may include processes that remove or etch material on a surface using etchants to form recessed features, such as a trench or an opening. For example, the etchants may impinge on a substrate, thereby removing portions of exposed material on the surface to form the recessed features.

When the etching or removal processes are performed under conventional conditions, the exposed material can become damaged by high-energy etchants that impinge upon it. An example of the damages is “microtrenching”. Microtrenching may occur due to increased etching at certain locations within the recessed features. For example, “micro-trenches” may be formed in the proximity of sidewalls in a bottom portion of the recessed feature, e.g., in a trench bottom. Microtrenching may lead to decreased reliability of the semiconductor devices due to reduced adhesion of subsequently deposited layers in the recessed features. Further, microtrenching may contribute to an increase in line-to-line leakage due to a localized increase in current densities within the micro-trenches.

### SUMMARY

In an aspect of the present disclosure, there is provided a structure in a semiconductor device, the structure having a lower surface, an upper surface above the lower surface, and at least one side having a corrugated surface, the corrugated surface including a plurality of ridges, the ridges are elongated and extend from the upper surface to the lower surface.

In another aspect of the present disclosure, there is provided a semiconductor device having a dielectric layer, a structure in the dielectric layer, the structure having at least one side having a corrugated surface, a lower surface, and an upper surface above the lower surface, the corrugated surface including a plurality of ridges, the ridges are elongated and extend from the upper surface to the lower surface.

In yet another aspect of the present disclosure, there is provided a method of forming a structure in a semiconductor device, the method includes forming a structure in a dielectric layer, the structure including at least one side having a corrugated surface, a lower surface, and an upper surface above the lower surface, the corrugated surface including a plurality of ridges, the ridges are elongated and extend from the upper surface to the lower surface.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1A through FIG. 1D are top-down views of example structures for use in conductive lines.

FIG. 2 is a perspective view of the example structure shown in FIG. 1B.

FIG. 3A and FIG. 3B are enlarged top-down views depicting example arrangements of ridges on sides of the structures.

FIG. 4A through FIG. 4E are enlarged top-down views depicting example shapes of ridges on sides of the structures.

FIG. 5 is a top-down view depicting an example layout of a conductive line having the structure shown in FIG. 1B.

FIG. 6 is a top-down view depicting another example layout of a conductive line having the structure shown in FIG. 1B.

FIG. 7 is a cross-sectional view depicting an example semiconductor device having conductive lines.

FIG. 8A, FIG. 8B, FIG. 9, and FIG. 10 depict structures at various stages of forming a structure for use in conductive lines.

FIG. 8A is a cross-sectional view and FIG. 8B is a top-down view illustrating the patterning of a resist layer above a dielectric layer. FIG. 8A is a cross-sectional view taken along section line AA in FIG. 8B.

FIG. 9 is a cross-sectional view illustrating the formation of a trench in the dielectric layer.

FIG. 10 is a cross-sectional view illustrating the formation of a conductive line in the dielectric layer.

### DETAILED DESCRIPTION

Various illustrative embodiments of the present disclosure are described below. The embodiments disclosed herein are exemplary and not intended to be exhaustive or limiting to the present disclosure.

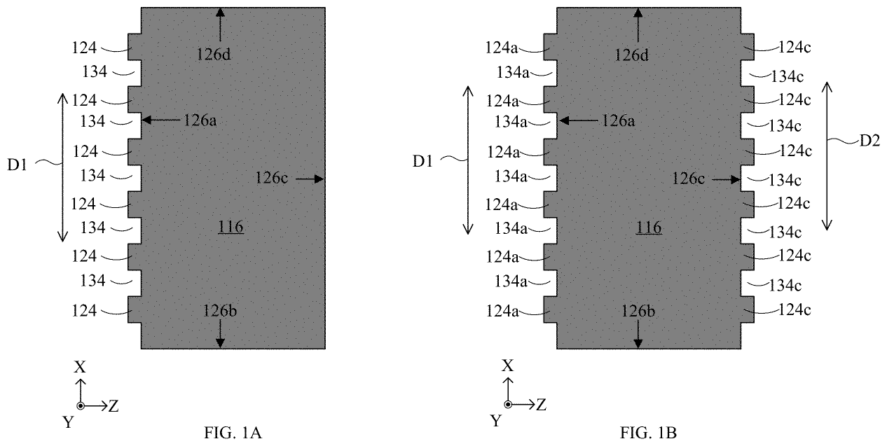

Referring to FIG. 1A through FIG. 1D, top-down views of exemplary structures 116 for use in conductive lines are presented. The structure 116 includes at least one side having a corrugated surface, a lower surface, and an upper surface above the lower surface. The corrugated surface includes a plurality of ridges 124. The ridges 124 may be arranged along a horizontal direction substantially parallel to the side with the corrugated surface. In the examples shown in FIG. 1A through FIG. 1D, the ridges 124 may be arranged along a horizontal direction D1, D2, D3 substantially parallel to either the X axis or the Z axis. As will be shown in subsequent drawings, the ridges 124 are elongated and extend from the upper surface of the structure 116 to the lower surface of the structure 116. The ridges 124 may alternatively be referred to as corrugation structures, protrusions, or raised portions of the structure 116. The corrugated surface may also include a plurality of grooves 134. The grooves 134 and the ridges 124 may be arranged in an alternating configuration. In particular, two adjacent ridges may be spaced apart by each groove. In the embodiments shown in FIG. 1A through FIG. 1D, the structure 116 may have a first side 126a, a second side 126b, a third side 126c, and a fourth side 126d.

As shown in FIG. 1A, the structure 116 may have a single side 126a with the corrugated surface. The other sides 126b, 126c, 126d may each have a substantially planar surface. The corrugated surface on the side 126a may include a plurality of ridges 124 and grooves 134. The ridges 124 and the grooves 134 may be both arranged along a horizontal direction D1 substantially parallel to the side 126a. In the example shown in FIG. 1A, the direction D1 may be parallel to the X axis.

As shown in FIG. 1B and FIG. 1C, the structure 116 may have two sides, each of the two sides having a corrugated surface. In the example shown in FIG. 1B, the structure 116 may have a first side 126a and a second side 126c. The first side 126a and the second side 126c may each have a corrugated surface. The other sides 126b and 126d may have substantially planar surfaces. The corrugated surface on the first side 126a may include a first plurality of ridges 124a and grooves 134a. The corrugated surface on the second side 126c may include a second plurality of ridges 124c and grooves 134c. The first plurality of ridges 124a and grooves 134a may be arranged along a horizontal direction D1 substantially parallel to the first side 126a, and the second plurality of ridges 124c and grooves 134c may be arranged along a horizontal direction D2 substantially parallel to the second side 126c. In some embodiments, the first side 126a may be oppositely facing the second side 126c such that the first plurality of ridges 124a and grooves 134a are oppositely facing the second plurality of ridges 124c and grooves 134c. In the example shown in FIG. 1B, the directions D1 and D2 may be parallel to the X axis.

In the example shown in FIG. 1C, the structure 116 may have side 126a with a corrugated surface and side 126d with a corrugated surface. The other sides 126b and 126c may have substantially planar surfaces. The corrugated surface on the side 126a may include a plurality of ridges 124a and grooves 134a while the corrugated surface on the side 126d may include a plurality of ridges 124d and grooves 134d. The plurality of ridges 124a and grooves 134a may be arranged along a horizontal direction D1 substantially parallel to the side 126a, and the second plurality of ridges 124c may be arranged along a horizontal direction D3 substantially parallel to the side 126d. In some embodiments, the side 126a may adjoin the side 126d. In particular, side 126a may be positioned at a right angle with respect to side 126d, and the direction D1 may be perpendicular to the direction D3. In the example shown in FIG. 1C, the direction D1 may be parallel to the X axis while the direction D3 may be parallel to the Z axis.

As shown in FIG. 1D, the structure 116 may have three sides, e.g., a first side 126a, a second side 126c, and a third side 126d. Each of the three sides 126a, 126c, 126d has a corrugated surface. The corrugated surface on the first side 126a may include a first plurality of ridges 124a and grooves 134a. The corrugated surface on the second side 126c may include a second plurality of ridges 124c and grooves 134c. The corrugated surface on the third side 126d may include a third plurality of ridges 124d and grooves 134d. The first plurality of ridges 124a and grooves 134a may be arranged along a horizontal direction D1 substantially parallel to the first side 126a, the second plurality of ridges 124c and grooves 134c may be arranged along a horizontal direction D2 substantially parallel to the second side 126c, and the third plurality of ridges 124d and grooves 134d may be arranged along a horizontal direction D3 substantially parallel to the third side 126d. In some embodiments, the first side 126a may be oppositely facing the second side 126c such that the first plurality of ridges 124a and grooves 134a are oppositely facing the second plurality of ridges 124c and grooves 134c. Additionally, the third side 126d may be positioned between the first side 126a and the second side 126c, in which the third side 126d adjoins the first side 126a and the second side 126c. In particular, the side 126d may be positioned at a right angle with respect to sides 126a, 126c. In the example shown in FIG. 1D, the directions D1 and D2 may be parallel to the X axis while the direction D3 may be parallel to the Z axis.

Although not shown in the accompanying drawings, the present disclosure also contemplates embodiments where the corrugated surface may be formed on all four sides 126a, 126b, 126c, 126d of the structure 116. Similar to the embodiments shown in FIG. 1A through FIG. 1D, the corrugated surface on each of the four sides may include a plurality of ridges and grooves. The ridges and grooves may be arranged along horizontal directions substantially parallel to the respective sides.

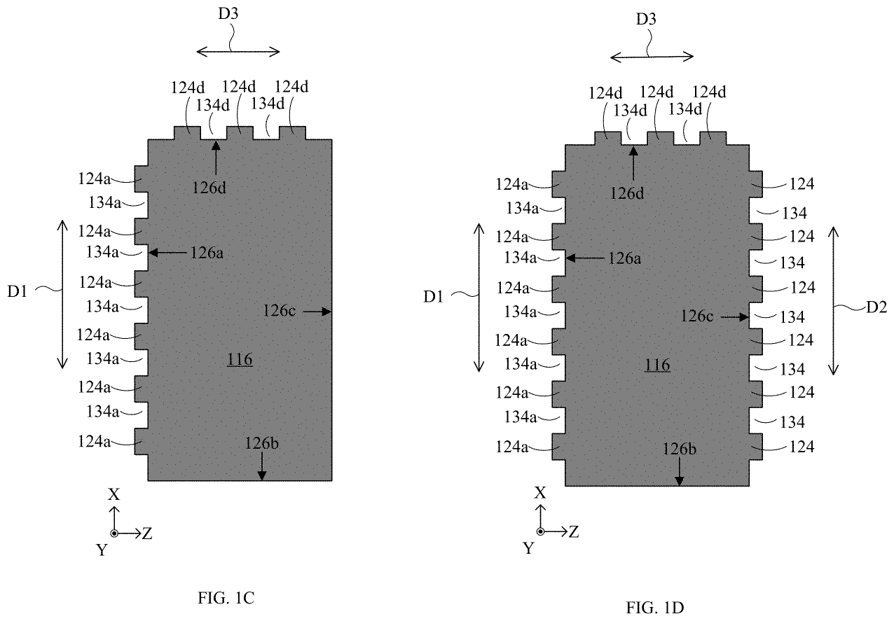

Referring to FIG. 2, a perspective view of the structure 116 in FIG. 1B is presented. The structure 116 may have an upper surface 136a and a lower surface 136b. The structure 116 may have a thickness T defined as the distance between the upper surface 136a and the bottom surface 136b. As described herein, the corrugated surface on the side 126a may include a first plurality of ridges 124a and grooves 134a, and the corrugated surface on the side 126c may include a second plurality of ridges 124c and grooves 134c. The ridges 124a and grooves 134a in the first plurality may be arranged along a horizontal direction D1 substantially parallel to the side 126a. The ridges 124c and grooves 134c in the second plurality may be arranged along a horizontal direction D2 substantially parallel to the side 126c. Directions D1 and D2 may be substantially parallel to the X axis. As described above, each ridge 124a, 124c in the respective first and second pluralities of ridges is elongated and extend from the upper surface 136a to the lower surface 136b, or from the lower surface 136b to the upper surface 136a. In an example, each ridge 124a, 124c may be substantially parallel to the Y axis.

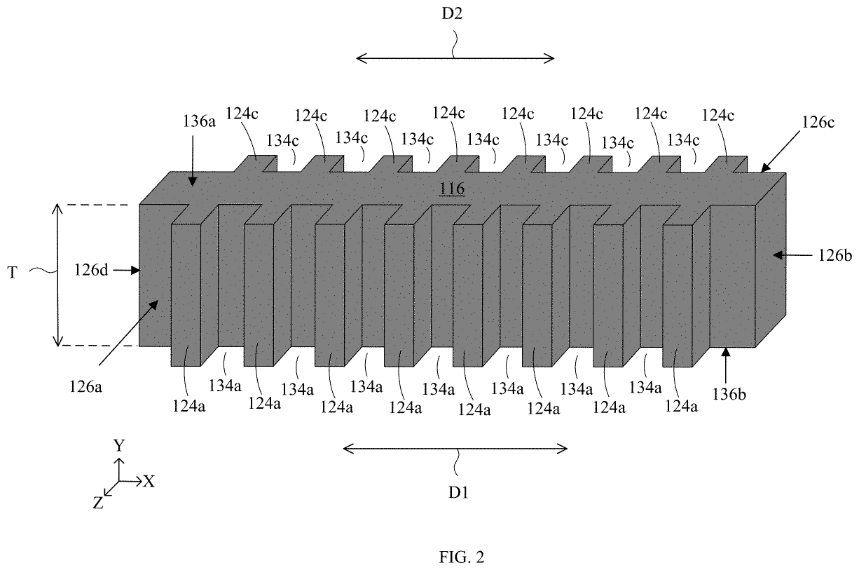

Referring to FIG. 3A and FIG. 3B, enlarged top-down views of a portion of the structure 116 in FIG. 1B are presented. The plurality of ridges 124a, 124c in the corrugated surfaces on the respective sides 126a, 126c may have a substantially constant pitch P. Additionally, the ridges 124a on the side 126a may have the same pitch as the ridges 124c on the side 126c. The pitch P may be defined as a distance between two laterally adjacent ridges arranged along the respective sides 126a, 126c. In an embodiment, each groove 134a, 134c may have a width that is equal to the pitch P in the respective plurality of ridges 124a, 124c. The ridges 124a, 124c on the respective sides 126a, 126c may have a substantially constant width W. Additionally, the ridges 124a on the side 126a may have the same width as the ridges 124c on the side 126c.

In the example shown in FIG. 3A, the ridges 124a on side 126a may be substantially aligned with the ridges 124c on side 126c. Alternatively, in the example shown in FIG. 3B, the ridges 124a on side 126a may not be aligned with the ridges 124c on side 126c, i.e., the ridges 124a on side 126a may be positioned offset from the ridges 124c on side 126c. In particular, the ridges 124a may each have a vertical axis 150 and the ridges 124c may each have a vertical axis 152. The vertical axis 150,152 of the respective ridge 124a, 124c may be defined as a straight line positioned midway between sidewalls of the respective ridge 124a, 124c. The vertical axes 150 of the ridges 124a may be positioned offset from the vertical axes 152 of the ridges 124c by a lateral distance S.

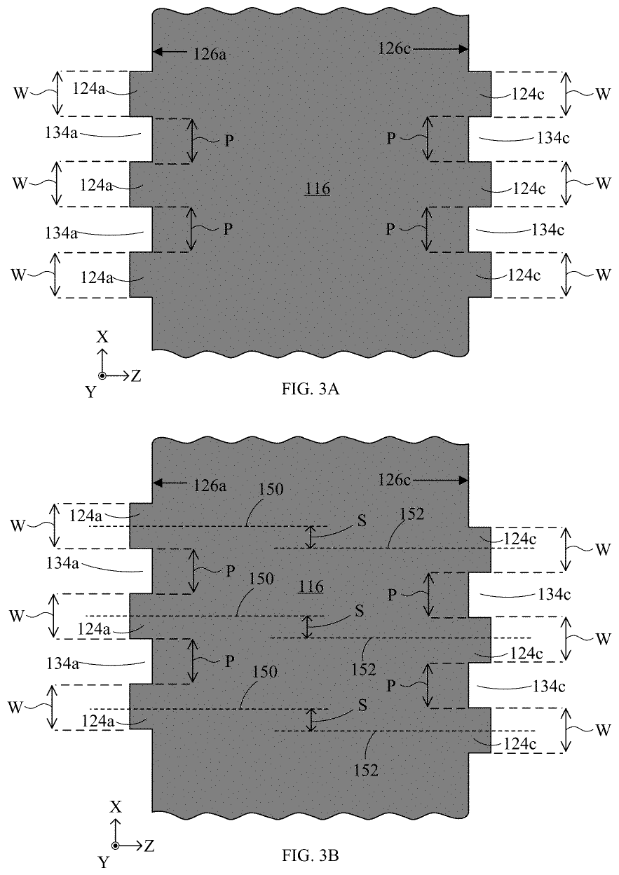

Referring to FIG. 4A through FIG. 4E, exemplary geometrical shapes of the ridges 124 are presented. FIG. 4A through FIG. 4E are enlarged top-down views of a portion of the structure 116 shown in FIG. 2.

As shown in FIG. 4A and FIG. 4B, each ridge 124a may have a surface 123c and a pair of sidewalls 123a, 123b. The surface 123c of each ridge 124a may be raised above the side 124a. The surface 123c and the sidewalls 123a, 123b may be elongated and extend from the upper surface of the structure 116 to the lower surface of the structure 116. The pitch P may be measured by a distance between the respective surfaces 123c of two laterally adjacent ridges 124a on the side 126a. In the example shown in FIG. 4A, the sidewalls 123a, 123b may be substantially parallel with each other. Alternatively, in the example shown in FIG. 4B, the sidewalls 123a, 123b may be tapered towards each other as they meet the upper surface 123c of each ridge 124a.

As shown in FIG. 4C, each ridge 124a may have a surface 123c and a pair of sidewalls 123a, 123b. The surface 123c may be an edge. The edge 123c of each ridge 124a may be raised above the side 126a. The edge 123c and the sidewalls 123a, 123b may be elongated and extend from the upper surface of the structure 116 to the lower surface of the structure 116. The pitch P may be measured by a distance between the respective edges 123c of two laterally adjacent ridges 124a on the side 126a.

As shown in FIG. 4D, each ridge 124a may be rounded. The rounded ridge 124a may have a convex surface that is raised radially outwards from the side 126a and have an apex point 123. The rounded ridge 124a and its apex point 123 may be elongated and extend from the upper surface of the structure 116 to the lower surface of the structure 116. The pitch P may be measured by a distance between the respective apex points 123 of two laterally adjacent ridges 124a on the side 126a.

FIG. 4E illustrates an alternative example arrangement of the plurality of ridges shown in FIG. 4C. As shown in FIG. 4E, the ridges 124a may have sidewalls 123a, 123b that are tapered towards each other. Additionally, the tapered sidewall 123b of one ridge 124a may meet the tapered sidewalls 123a of another adjacent ridge 124a. Accordingly, each groove 134a between two laterally adjacent ridges 124a may be referred to as “V-shaped” groove.

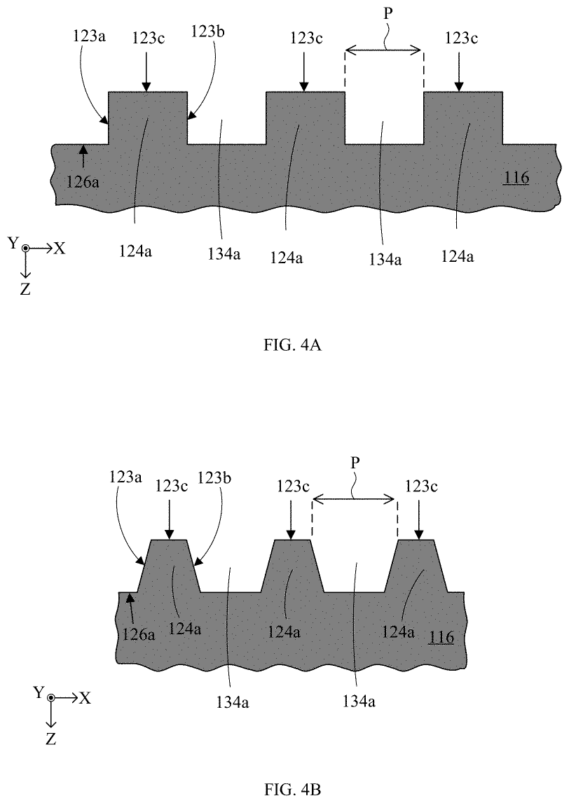

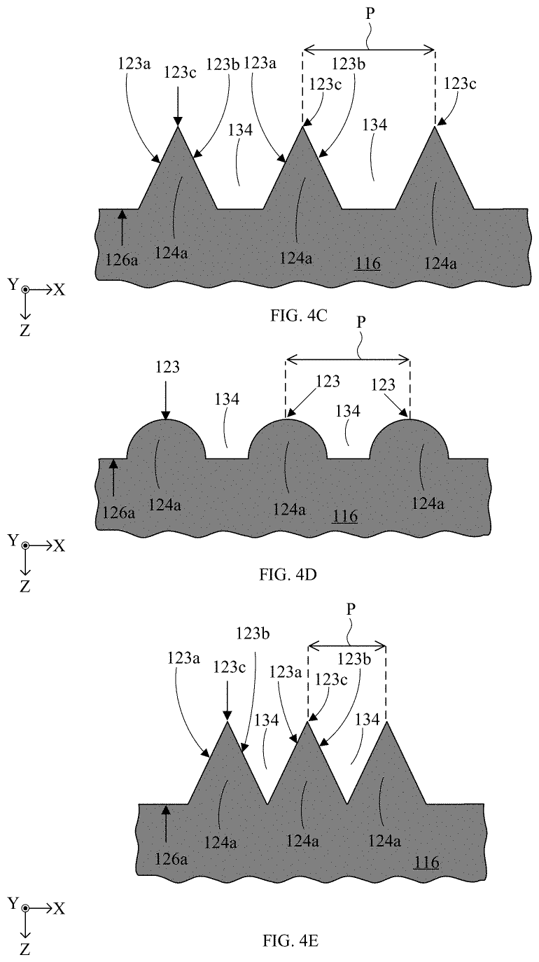

The structures 116 disclosed herein may be incorporated in the design of conductive lines in a back end of line (BEOL) portion of an integrated circuit (IC) chip. FIG. 5 and FIG. 6 illustrate example layout designs of conductive lines which incorporate the example structure 116 shown in FIG. 1B. Although not shown, it should be noted that the present disclosure also contemplates other layout designs of conductive lines which incorporate the example structures 116 shown in FIG. 1A, FIG. 1C, and FIG. 1D.

Referring to FIG. 5, an example layout of a conductive line 200 is presented. As shown, the conductive line 200 may include a comb-like layout. For example, the conductive line 200 may include one or more structures 116. The structures 116 may include two sides having the corrugated surfaces as described herein. The structures 116 may be arranged in a parallel arrangement and may be joined to an interconnect wiring 156.

Referring to FIG. 6, another example layout of a conductive line 300 is presented. As shown, the conductive line 300 may include a serpentine-like layout. For example, the conductive line 200 may include one or more structures 116. The structures 116 may include two sides having the corrugated surfaces as described herein. The structures 116 may be joined to each other in a series arrangement by bends 158 in the conductive line 300.

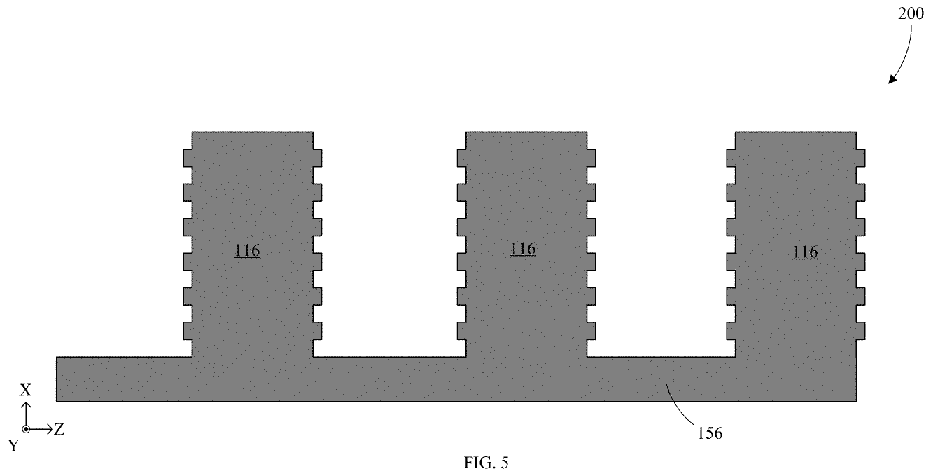

Referring to FIG. 7, a cross-sectional view of an example semiconductor device 100 having conductive lines is presented. The semiconductor device 100 may include a substrate 102, a transistor 110 disposed on the substrate 102, and inter-level dielectric (ILD) regions 112, 122, 132 disposed above the substrate 102 and the transistor 110. The transistor 110 may include source/drain regions 104, 108, and a gate 106 disposed between the source/drain regions 104, 108. The source/drain regions 104, 108 may be disposed in the substrate 102. Other active components may also be formed on the substrate 102. Examples of active components may include diodes (e.g., single-photon avalanche diode) or transistors such as, but not limited to, planar field-effect transistor, fin-shaped field-effect transistors (FinFETs), ferroelectric field-effect transistors (FeFETs), complementary metal-oxide semiconductor (CMOS) transistors, and bi-polar junction transistors (BJT). These active components may be formed by a front end of line (FEOL) processing of an IC chip.

The ILD regions 112, 122, 132 may include dielectric layers 118, 128, 138. The dielectric layers 118, 128, 138 may include, but are not limited to, silicon dioxide, tetraethyl orthosilicate (TEOS), or a material having a chemical composition of SiCₓO_{y}H_{z}, wherein x, y, and z are in stoichiometric ratio. The term “inter-level dielectric region” as used herein may refer to a region formed by the BEOL processing of an IC chip. The semiconductor device 100 may include a plurality of ILD regions. For example, an “n” number of ILD regions may be formed in the semiconductor device. As illustrated in FIG. 7, the device may include 3 ILD regions 112, 122, 132, in which the number “n” is 3. Other numbers of ILD regions may also be useful. The number of ILD regions may depend on, for example, design requirements or the process involved.

Each ILD region 112, 122, 132 may include a contact level 112a, 122a, 132a, respectively, and a metal level 112b, 122b, 132b, respectively. The ILD regions 112, 122, 132 may also include various interconnect features (e.g., interconnect vias 114, conductive lines 216, contact structures 113). The interconnect features may connect various devices or components within the IC chip to perform desired functions. In particular, each contact level 112a, 122a, 132a includes the interconnect vias 114 or the contact structures 113 while each metal level 112b, 122b, 132b includes the conductive lines 216. The conductive lines 216 may provide routing or wiring of electrical signals across various components in the IC chip. The contact structures 113 may provide electrical connections between the transistor 110 and the conductive line 216 while the interconnect vias 114 may provide electrical connections between the respective conductive lines 216 in the metal levels 112b, 122b, 132b. The conductive lines 216 in each of the ILD regions 112, 122, 132 may include the structure 116 described in FIG. 1A through FIG. 4E. The conductive lines 216 may have various design layouts, such as those described in FIG. 5 and FIG. 6.

The interconnect vias 114, the contact structures 113, and the conductive lines 216 may be include a metal, such as tantalum (Ta), tungsten (W), ruthenium (Ru), cobalt (Co), copper (Cu), titanium (Ti), nickel (Ni), platinum (Pt), aluminum (Al), or an alloy thereof. Other suitable types of metal, alloys, or conductive materials may also be useful. The interconnect features may be formed using a damascene process (e.g., a single damascene or a dual damascene). In some cases, the interconnect vias 114 and the conductive lines 216 in ILD regions 122, 132 may be of the same material and may be formed by dual damascene processes. In some cases, the contact structures 113 and the conductive lines 216 may be of different materials. For example, in the case where the contact structures 113 and the conductive lines 216 are formed by single damascene processes, the materials of the contact structures 113 and the conductive lines 216 may be different from each other. Other techniques, such as reactive ion etch (RIE) may also be employed to form the conductive lines 216.

Dielectric liners 120, 130 may be disposed between the respective dielectric layers 118, 128, 138. The dielectric liners 120, 130 may include, but are not limited to, silicon dioxide (SiO₂), silicon oxynitride (SiON), silicon nitride (SiN), Nitrogen doped silicon carbide (SiCN), SiCₓHₓ (i.e., BLoK™), or SiN_{w}CₓH_{z} (i.e., NBLoK™), wherein each of w, x, y, and z independently has a value greater than 0 and less than 0.75.

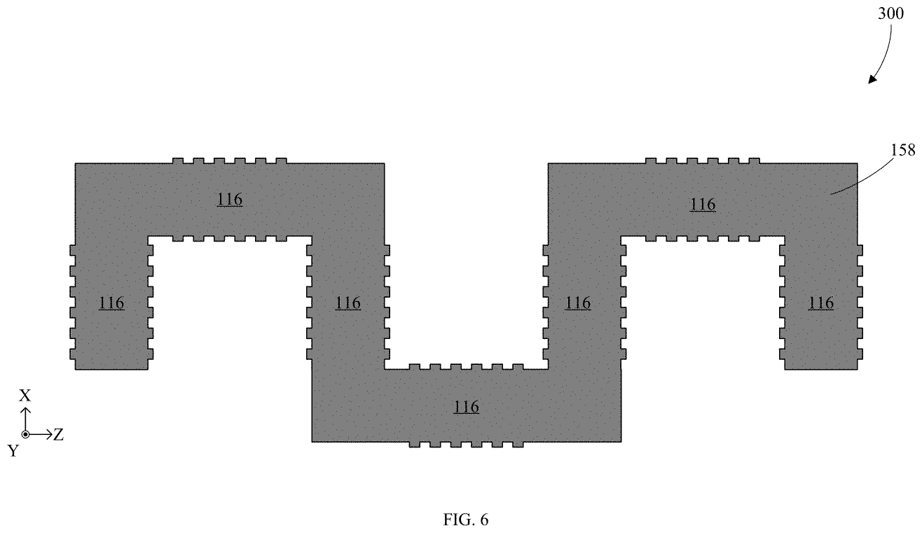

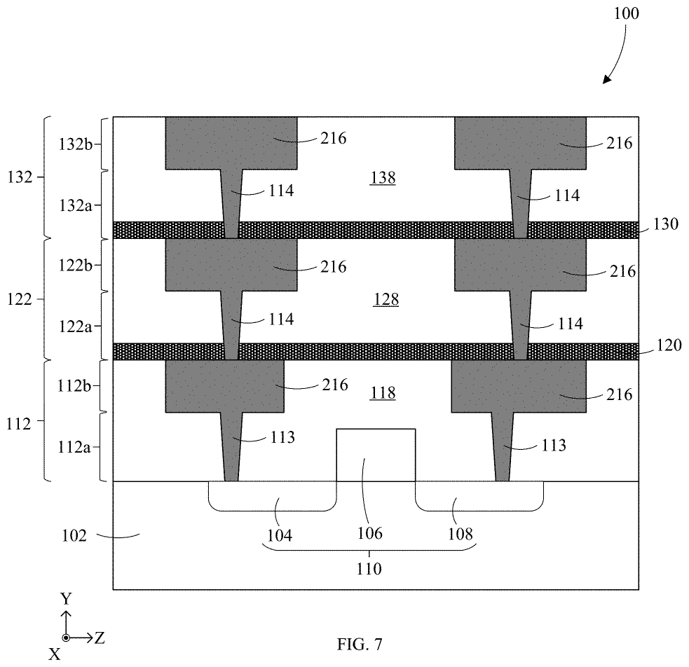

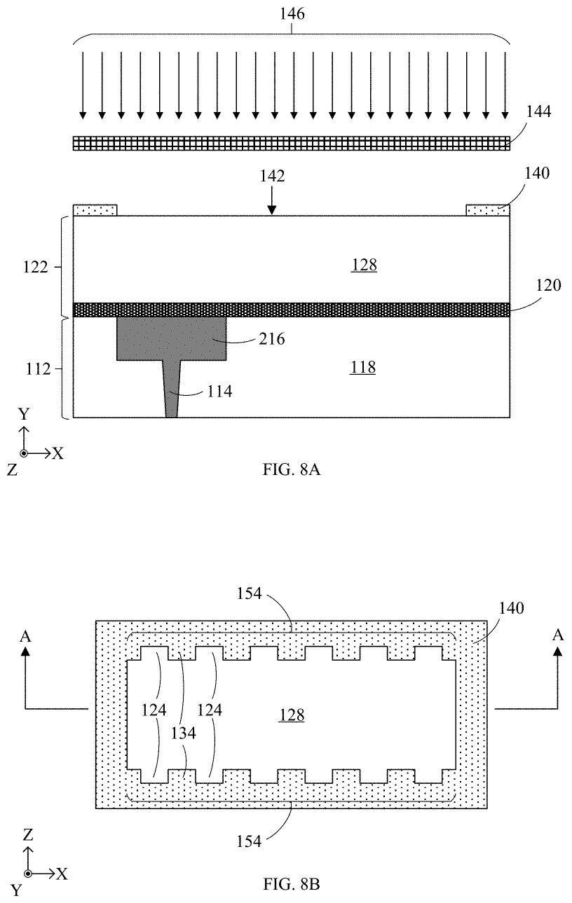

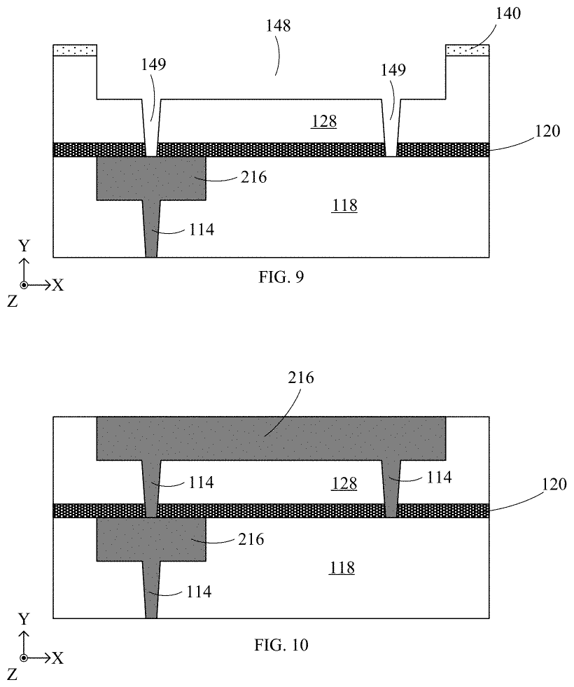

FIG. 8A, FIG. 8B, FIG. 9, and FIG. 10 show a set of steps that may be used to form a conductive line in a semiconductor device.

As used herein, “deposition techniques” refer to the process of applying a material over another material (or the substrate). Exemplary techniques for deposition include, but are not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” includes deposition of material or photoresist, patterning, exposure, development, etching, cleaning, and/or removal of the material or photoresist as required in forming a described pattern, structure or opening. Examples of techniques for patterning include, but not limited to, wet etch lithographic processes, dry etch lithographic processes or direct patterning processes. Such techniques may use mask sets and resist layers.

Referring to FIG. 8A and FIG. 8B, a device structure for use in the BEOL fabrication of an IC chip is presented. The device structure includes a first ILD region 112 and a second ILD region 122. The first ILD region 112 may include a first dielectric layer 118. An interconnect via 114 and a conductive line 216 may be formed in the first dielectric layer 118. A dielectric liner 120 may be formed over the first dielectric layer 118 and the conductive line 216 in the first dielectric layer 118. The second ILD region 122 may be formed above the first ILD region 112. The second ILD region 122 may include a second dielectric layer 128. The second dielectric layer 128 may have an upper surface 142.

A resist layer 140 may be formed on the upper surface 142 of the second dielectric layer 128 using the deposition techniques described herein. The deposited resist layer 140 may be patterned using the patterning techniques described herein to expose portions of the upper surface 142 of the second dielectric layer 128. The exposed portions of the upper surface 142 of the second dielectric layer 128 may be etched. The patterning of the resist layer 140 may include the use of a mask 144 and exposure to, for example, ultraviolet (UV) light 146. The mask 144 may include layout patterns for the patterning of the resist layer 140. The layout patterns in the mask 144 may be transferred to the patterned resist layer 140 using photolithographic techniques.

As shown in FIG. 8B, the exposed portions of the upper surface of the dielectric layer 128 may have an outline defined by the patterned resist layer 140. The outline of the exposed upper surface may include at least one corrugated outline 154, the corrugated outline 154 including a plurality of ridges 124 and grooves 134. The ridges 124 and grooves 134 may be arranged in an alternating configuration, and each groove 134 may be positioned between two laterally adjacent ridges 124.

Referring to FIG. 9, the second dielectric layer 128 may be patterned to define a trench 148 and openings 149 in the second dielectric layer 128. For example, the second dielectric layer 128 may be patterned using an etching process (e.g., dry etch or plasma etching). The dry etch may include the generation of ions which may impinge on the exposed upper surface 142 of the second dielectric layer 128, thereby removing portions of the exposed material to form the trench 148 and the openings 149. Formation of the trench 148 and the openings 149 may include one or more etching steps. In an embodiment, the second dielectric layer 128 may be etched to form the trench 148 with corrugated sidewalls that correspond to the corrugated outlines of the exposed upper surface of the second dielectric layer 128. The resist layer 140 may be subsequently removed, e.g., using an ashing step.

Referring to FIG. 10, a conductive line 216 and interconnect vias 114 may be formed in the second dielectric layer 128, for example, using a damascene process. In an embodiment, a metal may be deposited into the trench and the openings defined in the second dielectric layer 128 using the deposition techniques described herein. In particular, the deposited metal in the trench may form a structure having sides that conform to the corrugated sidewalls of the trench. Accordingly, the structure formed by the deposition of metal in the trench may have a corrugated surface on its sides, the corrugated surface including a plurality of ridges and grooves.

By designing a conductive line 216 incorporating a structure with a corrugated surface on at least one of its sides, it is found that a more evenly distributed plasma density can be achieved during the etching process. An even distribution of plasma density can achieve more uniform etching rates at all locations of the surface upon which the etchants are impinging. Accordingly, the size and depth of a micro-trench formed in a recessed feature (e.g., a trench) can be reduced. Furthermore, the presence of a corrugated surface on at least one side of the structure is found to increase the breakdown voltage of the conductive line 216. With an increased breakdown voltage, the conductive lines 216 as described herein may be formed with a longer length as compared to conductive lines without any corrugated surfaces.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description. Additionally, the various tasks and processes described herein may be incorporated into a more comprehensive procedure or process having additional functionality not described in detail herein.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

As will be readily apparent to those skilled in the art upon a complete reading of the present application, the disclosed structures in semiconductor devices and the methods of forming the structures in the semiconductor devices may be employed in manufacturing a variety of different integrated circuit products, including, but not limited to, logic devices, memory devices, radio frequency applications, high power applications, etc.

What is claimed is:

1. A structure in a semiconductor device, the structure comprising:
a lower surface;
an upper surface above the lower surface; and
at least one side having a corrugated surface, the corrugated surface comprising a plurality of ridges, the ridges are elongated and extend from the upper surface to the lower surface.

2. The structure of claim 1, further comprising:
a first side having a corrugated surface, the corrugated surface on the first side comprises a first plurality of ridges arranged along a horizontal direction parallel to the first side; and
a second side having a corrugated surface, the corrugated surface on the second side comprises a second plurality of ridges arranged along a horizontal direction parallel to the second side.

3. The structure of claim 2, wherein the first side is oppositely facing the second side.

4. The structure of claim 3, wherein the ridges on the first side are substantially aligned with the ridges on the second side.

5. The structure of claim 3, wherein the ridges on the first side are positioned offset from the ridges on the second side.

6. The structure of claim 2, wherein the second side adjoins the first side.

7. The structure of claim 3, further comprising a third side having a corrugated surface, the corrugated surface on the third side comprises a third plurality of ridges arranged along a horizontal direction parallel to the third side, wherein the third side is between the first side and the second side.

8. The structure of claim 7, wherein the third side is at right angles to the first side and the second side.

9. The structure of claim 1, wherein each ridge in the plurality of ridges has a pair of sidewalls and a surface raised above the side with the corrugated surface.

10. The structure of claim 9, wherein the pair of sidewalls of each ridge are tapered towards each other as they meet the surface of each ridge.

11. The structure of claim 9, wherein the pair of sidewalls of each ridge are substantially parallel with each other.

12. The structure of claim 9, wherein the surface and the sidewalls of each ridge are elongated and extend from the upper surface of the structure to the lower surface of the structure.

13. The structure of claim 9, wherein the surface of each ridge in the plurality of ridges is an edge and the pair of sidewalls of each ridge taper towards each other as they meet the edge.

14. The structure of claim 1, wherein each ridge in the plurality of ridges is rounded and having a convex surface, the convex surface is raised radially outwards from the side with the corrugated surface.

15. The structure of claim 1, wherein the corrugated surface further comprises a plurality of grooves, and wherein the grooves and the ridges are arranged in an alternating configuration, and two laterally adjacent ridges are spaced apart by each groove.

16. The structure of claim 1, wherein the plurality of ridges has a substantially constant pitch.

17. A semiconductor device comprising:
a dielectric layer; and
a conductive line in the dielectric layer, the conductive line comprising a structure, the structure in the conductive line comprising at least one side having a corrugated surface, a lower surface, and an upper surface above the lower surface, the corrugated surface comprising a plurality of ridges, the ridges are elongated and extend from the upper surface to the lower surface.

18. The semiconductor device of claim 17, wherein the conductive line comprises a serpentine layout.

19. The semiconductor device of claim 17, wherein the conductive line comprises a comb layout.

20. A method of forming a conductive line in a semiconductor device, the method comprising:
forming a structure in a dielectric layer, the structure comprising at least one side having a corrugated surface, a lower surface, and an upper surface above the lower surface, the corrugated surface comprising a plurality of ridges, the ridges are elongated and extend from the upper surface to the lower surface.
